(19) United States
(12) Patent Application Publication
(10) Pub. No.: US 2017/0199245 A1
(43) Pub. Date: Jul. 13, 2017

(54) METHOD FOR MEASURING OR TESTING THE PERFORMANCE OF ACCUMULATORS

(71) Applicant: Younicos AG, Berlin (DE)

(72) Inventors: Roman Schneeweiss, Berlin (DE); Ina Hahndorf, Berlin (DE)

(21) Appl. No.: 15/468,790

(22) Filed: Mar. 24, 2017

Related U.S. Application Data
(63) Continuation of application No. PCT/EP2015/071952, filed on Sep. 24, 2015.

(30) Foreign Application Priority Data
Sep. 26, 2014 (DE) 102014219582.9

(51) Int. Cl. G01R 31/36

(52) U.S. Cl. CPC G01R 31/3627; G01R 31/3662; G01R 31/3679; G01R 31/3658

(57) ABSTRACT

In a method for measuring and testing the performance of accumulators by determining at least one of data or profiles characteristic for accumulators, a plurality of series connected accumulators in a first measurement phase are connected to a power supply unit and a load and are charged and discharged at least once, and first measurement values are detected, from which data or profiles characteristic for the series-connected accumulators are created, the series connection is separated and each individual accumulator one after the other is connected to the power supply unit and the load. In a second measurement phase each accumulator is completely charged and completely discharged at least once and predetermined second measurement values are detected, from which individual data or profiles characteristic for each accumulator are created.

### CROSS-REFERENCE TO RELATED PATENT APPLICATIONS

This application is a Continuation of International Application No. PCT/EP2015/071952, filed Sep. 24, 2015, which claims the benefit of and priority to German Patent Application No. 10 2014 219 582.9, filed Sep. 26, 2014, the entire disclosures of which are hereby incorporated by reference herein.

### BACKGROUND

This application relates to a method for measuring or testing the performance of accumulators and to an apparatus for carrying out the method.

For measuring accumulators, accumulator cells or accumulator packs, in particular for determining the performance and the energy content or the capacitance at the end of a charging operation or discharging operation and for determining the capacitance degradation, increase in impedance and/or internal resistance during a cyclization, i.e. when charging and discharging continuously to achieve an accelerated ageing of the accumulators, testing methods are employed, in which standardized measurement parameters are applied to the accumulators to be tested and from the respective measurement values characteristic data and profiles are determined, which are characteristic for the performance of the accumulators. As measurement parameters defined currents, voltages, powers, ambient temperatures, load profiles, typification profiles and temperature profiles are used and by means of control and measurement software measurement and load profiles, ageing profiles and degradation profiles are carried out under program control. From the measurement values, in particular from the charging and discharging current, the charging and discharging voltage as well as the temperature, the capacitance or the energy content of the accumulators and, on the basis of cyclization measurements to achieve an accelerated ageing, the capacitance degradation, increase in impedance and increase in internal resistance of the accumulators are determined.

What is disadvantageous in the known testing methods is the considerable amount of time required for determining the performance of individual accumulators. This is disturbing when applying the known testing methods for a selection of accumulators for particular fields of use, but when applying said methods for testing numerous accumulators used in a large storage device such as a battery power plant, this is not acceptable in operation of the large storage device because of the required insulation of the accumulators to be tested.

### SUMMARY

It is an object of the present application to indicate a method for measuring or testing the performance of accumulators by determining data and/or profiles characteristic for accumulators, which provides for testing a plurality of accumulators with minimum time and measurement expenditure and for measuring the accumulators in operation of a storage battery or battery power plant.

In accordance with the application, this object is solved with features as described herein.

The solution according to the application is to:
in a first measurement phase connect N series-connected accumulators to a power supply unit and by specifying predetermined first measurement parameters jointly charge the same, until an accumulator having the lowest capacitance of the N accumulators is charged completely, a measurement value corresponding to the capacitance of this accumulator is stored, and this accumulator is separated from the series connection,
in a second measurement phase recharge the remaining N−1 accumulators up to their full charge and store a measurement value corresponding to the capacitance of each of the N−1 accumulators,
in a third measurement phase again connect the series-connected N accumulators to a load and by specifying predetermined second measurement parameters discharge the same, until the accumulator having the lowest capacitance of the accumulators is discharged completely and is separated from the series connection,
and in a fourth measurement phase connect the N−1 accumulators not yet discharged completely to the load and discharge the same completely, in the first and third measurement phases provides for determining the cycle stability of the accumulators due to the series connection of the accumulators and the resulting joint charging and discharging of the accumulators, i.e. for determining the number of charges and discharges of the accumulators until falling below a specified capacitance value, in the shortest possible time, with minimum expenditure for manufacturing a measuring device and minimum time expenditure for equipping the measuring device with the accumulators to be measured and for carrying out the measurements and removing the accumulators to be measured. Another advantage of the method according to the application consists in that testing of accumulators in the installed condition, i.e. in operation of a storage battery, is possible without having to remove the accumulators and measure the same in the removed condition.

But since the accumulator with the lowest capacitance determines both the duration of charging and the duration of discharging of the series-connected accumulators, the remaining ones of the series-connected accumulators are not yet charged completely at the end of the first measurement phase or not yet discharged completely at the end of the third measurement phase. Correspondingly, in a second measurement phase the remaining N−1 accumulators are recharged up to their full charge and a measurement value corresponding to the capacitance of each of the N−1 accumulators is stored. In the fourth measurement phase following the third measurement phase the N−1 accumulators not yet discharged completely each are connected to the load and likewise discharged completely.

The complete charging and discharging of the remaining N−1 accumulators in the second and fourth measurement phases permits two alternative embodiments.

In a first variant, with or without the separation of the series connection of the N−1 accumulators, the accumulators not yet charged completely are individually connected to the power supply unit, recharged up to their respective full charge, and a measurement value corresponding to the capacitance of each of the N−1 accumulators is stored for the further determination of the individual cycle stability of the accumulators.

In the fourth measurement phase, with or without separation of the series connection of the accumulators, the N−1 accumulators not yet discharged completely likewise are individually connected to the load and discharged completely.

In the second measurement phase of the second variant, the remaining N−1 series-connected accumulators are recharged up to their respective capacitance limit and a measurement value corresponding to the capacitance of that accumulator which has reached its capacitance limit is stored, and this accumulator is separated from the series connection of the N−X accumulators, wherein N and X are integers, N>1 and 2<X<N.

In the fourth measurement phase, the series-connected N−1 accumulators not yet discharged completely analogously are connected to the load, discharged completely and the respective completely discharged accumulator is separated from the series connection of the N−X accumulators.

This second variant provides for a further saving of time, as in the second measurement phase, after full charging of the accumulator of the series-connected accumulators with the lowest capacitance, not each of the remaining accumulators is recharged individually up to reaching its capacitance limit, but the remaining accumulators are recharged jointly until the next accumulator reaches its capacitance limit, the respective capacitance value is stored and the remaining accumulators are recharged until reaching their respective capacitance limit and the respective capacitance values associated to the individual accumulators are stored.

In the fourth measurement phase the series-connected accumulators likewise initially are discharged jointly via the load, until the accumulator with the lowest capacitance is discharged completely. The same is removed from the series connection or isolated in terms of circuitry and the remaining accumulators are discharged further, until the next accumulator is discharged completely, etc.

When applying both measurement methods, a measure for the cycle stability of the individual accumulators already is obtained from completely charging and discharging the accumulators for one time in conjunction with corresponding experience values and comparative measurements. By repeatedly charging and discharging the accumulators, the accuracy of the measurements can be increased, ageing and degradation curves of the individual accumulators can be determined, wherein the reduction of time as a result of the series connection of the accumulators is potentiated correspondingly with several charging and discharging operations.

As criterion for reaching the capacitance limit reaching of the end-of-charge voltage is employed and as criterion for the complete discharge of the accumulators the end-of-discharge voltage is employed, wherein as first or second measurement parameters the charging current, the charging voltage, the charging time, the charging power, the charging energy and the temperature of the series-connected accumulators or of each individual accumulator and possibly in addition the ambient temperature are provided, wherein the charging time is required for determining the charge or capacitance in ampere-hours (Ah) and the energy in watt-hours (Wh).

In a fifth measurement phase each of the N accumulators can individually be connected to the power supply unit and load and can be charged and discharged at least once to determine its specific properties such as capacitance, impedance or internal resistance and to record measurement, load, temperature, ageing and/or degradation curves.

From the first or second measurement values the capacitance and the energy content of each individual accumulator is determined, while from the second measurement values individual measurement, load, ageing and/or degradation profiles are created for each individual accumulator under program control by means of a control and measurement software.

A preferred embodiment of the method according to the application consists in that in the first or second measurement phase a preferably programmed, predetermined cyclization and/or load profile is carried out for the accelerated ageing, capacitance degradation, increase in impedance and increase in internal resistance of the series-connected accumulators and/or of each individual accumulator.

An apparatus for carrying out the method is characterized by a holder for accommodating accumulators with different dimensions and a switching device with controllable switches for the series connection of accumulators and connection of the series-connected accumulators to a power supply unit, a load and a measuring device, for separating the series connection and individually connecting each individual accumulator to the power supply unit, the load and the measuring device, wherein the switching device contains at least a number of controllable switching contacts corresponding to the number of accumulators to be measured, with which in the first and third measurement phases the accumulators are connectable in series to the power supply unit, to the load and to the measuring device, and with which after the first measurement phase the series connection can be separated, and in the fourth measurement phase each individual accumulator is connectable to the power supply unit, to the load and to the measuring device.

As load, there is preferably used an electronic load, which is a current sink in which in contrast to loading with a fixed resistor, with which only a particular load current with a particular resistance value can be adjusted, a load current is adjustable in a defined range under electronic control.

For zero-point lowering on charging and discharging of the accumulators, the negative pole of the electronic load is connected with the negative pole of a voltage source whose positive pole is connected to the negative pole of the power supply unit via a Z-diode.

To be able to connect the accumulators to only one power supply unit, one (electronic) load and one measuring device with little apparatus expenditure and space requirement, the switching contacts consist of a relay circuit with a number of relay contacts, which corresponds to twice the number of the accumulators to be connected in series, wherein a first measurement sensor for detecting the first and second measurement values is connected to an electrical contact of a first accumulator, and further measurement sensors are connected to the connections of the electrical contacts of the series-connected accumulators.

To minimize the time expenditure when connecting the accumulators to the measuring device, the charging and measuring contacts of the measurement sensors consist of pressure pin contacts, so that contacting of the accumulators can be effected without screws, clamps or solder connections.

The pressure pin contacts contain a contact surface which has a surface structure formed in the manner of a waffle iron, so that a very good contact is ensured for contacting to transmit even high currents with easy handling. The waffle-iron-like surface structure ensures that oxide layers or dirt deposits also are penetrated for proper contacting.

To minimize the expenditure for measuring devices, the holder includes steplessly adjustable receptacles for accumulators of a particular type of accumulator with different outside dimensions and/or distances of the electrical contacts of the accumulators, whereby the manufacturing expenditure for measuring devices is minimized and an easy handling and correct alignment of the accumulators to be measured and tested in the measuring device is ensured.

Due to the different geometry of the most important types of accumulator, holders for so-called “pouch cells” and for prismatic accumulators or accumulator cells are provided.

A first holder for accumulators formed as pouch cells consists of a box-shaped rack with a base plate, a cover plate and at least one guide plate between the cover plate and the base plate, wherein the cover plate and the at least one guide plate include guide slots for accommodating the pouch cells, wherein the length of the guide slots corresponds to the maximum width of pouch cells.

Preferably, the at least one guide plate is insertable into the space formed between the cover plate and the base plate so as to be rotatable in the plane by 180° such that in the one alignment of the guide plate for accommodating long pouch cells the guide slots arranged in the guide plate are aligned with the guide slots arranged in the cover plate, and in the other alignment of the guide plate for accommodating short pouch cells the guide slots arranged in the guide plate are arranged offset to the guide slots arranged in the cover plate.

The holder according to the application provides for a steplessly variable adjustment for accommodating pouch cells of various outside dimensions, wherein the adjustability is obtained via the guide slots whose length corresponds to the maximum width of commercially available pouch cells. To be able to hold short and long pouch cells, a variably usable and height-adjustable guide plate is provided, on which short pouch cells rest due to the offset of the guide slots of the guide plate with respect to the guide slots of the cover plate, whereas with a flush alignment of the guide slots of cover plate and guide plate long pouch cells come to rest on the base plate.

Electrical contacting for charging and discharging of the pouch cells as well as contacting of the measurement sensors is effected via pressure pin contacts independent of the respective size of the pouch cells, as the contact tabs of the pouch cells each are formed of the same size.

For prismatic accumulators a second holder consists of a carrier plate with receptacles for the prismatic accumulators and steplessly adjustable guide rails for guiding measurement and charging contact carriers which are adjustable parallel to the plane of the electrical contacts of the accumulators, wherein the receptacles for the prismatic accumulators consist of guide bolts and stops whose position on the carrier plate is adaptable to the outside dimensions of the prismatic accumulators.

To provide for measuring accumulators at defined ambient temperatures, the holders are dimensioned such that they can be inserted into a heating cabinet with which the corresponding ambient temperatures can be produced . . .

### BRIEF DESCRIPTION OF THE DRAWINGS

With reference to exemplary embodiments illustrated in the drawing the idea underlying the application and variants of the method according to the application and of the apparatus for carrying out the application which can be derived therefrom, will be explained in detail.

FIG. 1 shows a circuit diagram of a measuring device for measuring accumulators in use of the method according to the application.

FIG. 2 shows a segment of the circuit diagram of the measuring device according to FIG. 1 for measuring accumulators in use of the second variant of the method according to the application.

FIG. 3 shows a schematic representation of the charging operation of series-connected accumulators after fully charging the accumulator with the lowest capacitance.

FIG. 4 shows a perspective representation of a measuring device with a holder adjusted for measuring long pouch cells.

FIGS. 5 and 6 show a top view and a side view of the measuring device for measuring long pouch cells according to FIG. 4.

FIG. 7 shows an enlarged representation of the segment V according to FIG. 6.

FIG. 8 shows a perspective representation of the measuring device according to FIGS. 4 to 5 with a setting of the holder for measuring short pouch cells.

FIG. 9 shows a perspective representation of a measuring device for measuring prismatic accumulators.

FIGS. 10-12 show various views of the measuring device according to FIG. 9 for measuring prismatic accumulators.

FIGS. 13-16 show various measurement curves recorded with measuring devices according to FIGS. 4-12.

### DETAILED DESCRIPTION

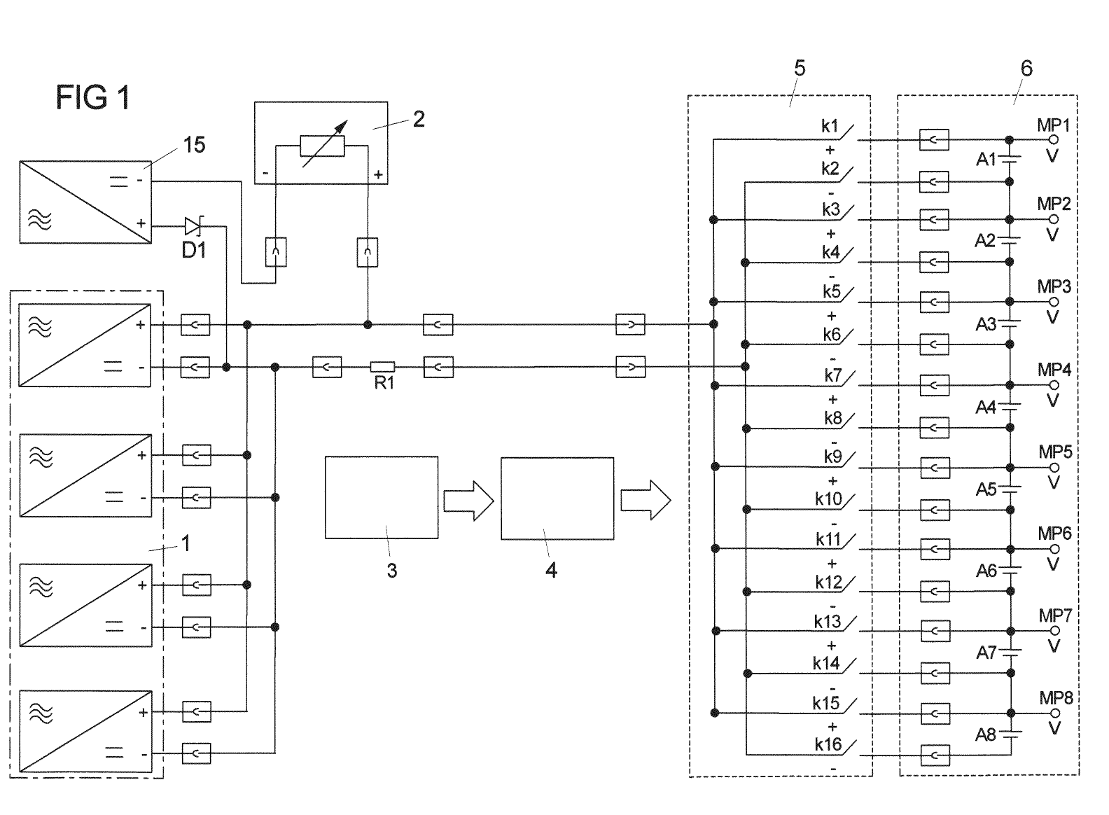

FIG. 1 shows a circuit diagram of an apparatus for measuring accumulators or accumulator cells with a power supply unit 1, an electronic load 2, a control device 3 for actuating an interface 4, which is connected both with a switching device 5 and with a measuring device for actuating measurement points MP1 to MP8. A holder 6 serves the accommodation of several accumulators A1 to A8 and the measurement points MP1 to MP8, wherein the contacts of the accumulators A1 to A8 are connected with individual switching contacts k1 to k16 of the switching device 5 and with the measurement points MP1 to MP8.

The power supply unit 1 consists of four rectifiers connected in parallel at the output end for outputting a d.c. voltage to the switching device 5 with charging and discharging powers in the range of e.g. 0 to 15 kW, a charging current in the range from 0 to 200 A, and charging voltages in the range from 0 to 600 V. To apply the required charging currents and charging voltages, the power supply unit 1 can consist of a larger number of rectifiers connected in parallel, which output the maximum charging voltage of 600 V and the maximum charging current of 200 A.

The electronic load 2 designated as variable resistor takes up a load current adjustable in a defined range under electronic control and is dimensioned such that it can take up discharging powers in the range from 0 to 15 kW, discharging currents in the range from 0 to 200 A and discharging voltages in the range from 0 to 600 V. The electronic load 2 can be regulated very quickly and can carry out exact and defined charging and discharging operations at very high currents and small voltages.

The power supply unit 1 and the electronic load 2 are connected with the switching device 5 via a pre-resistor R1.

For zero-point lowering when charging and discharging the accumulators A1-A8, the electronic load 2 is connected with a voltage source 15 whose positive pole is connected with the negative pole of the power supply unit 1 or the negative connecting terminals of the accumulators A1 to A8 via a Z-diode D1 and whose negative pole is connected with the negative pole of the electronic load 2.

In the exemplary embodiment shown in FIG. 1 the holder 6 accommodates eight series-connected accumulators A1 to A8, which via the switching contacts k1 to k16 of the switching device 5 formed as relay contacts are connected with the power supply unit 1 and the electronic load 2 for charging and discharging the accumulators A1 to A8. The odd relay contacts k1 to k15 are connected with the positive connecting terminals of the accumulators A1 to A8, and the even relay contacts k2 to k16 are connected with the negative connecting terminals of the accumulators A1 to A8.

For measuring or testing the performance of the accumulators A1 to A8, the series-connected accumulators A1 to A8 in a first measurement phase are connected to the power supply unit 1 and the electronic load 2 by closing the relay contacts k1 and k16 with open relay contacts k2 to k15.

Both measurement phases are carried out with an apparatus corresponding to the circuit diagram shown in FIG. 1, namely in the first measurement phase with closed relay contacts k1 and k16 with a series connection of the accumulators A1 to A8 and after completion of the first measurement phase with a separation of the series connection by means of the relay contacts k1 to k16 preferably formed as high-voltage and high-current relay for carrying out the second measurement phase, in which the contacts k1 and k2 to k15 and k16 each are closed. To ensure equal treatment of the accumulators A1 to A8, measuring of the individual accumulators A1 to A8 in the individual measurement is effected by means of random closing of the relay contacts k1 to k16, in order to carry out individual capacitance measurements independent of the state of charge and discharge of the individual accumulators A1 to A8.

The actuation of the relay contacts k1 to k16 as well as the recording of the measurement values detected at the measurement points MP1 to MP8 is effected via the interface 4 to an individually programmed control and measurement software of the computer control unit 3. The interface 4 actuates both the relay contacts of the switching device 5 and the connection of the measurement points MP1 to MP8 with the measuring device 16.

Beside measuring accumulators for determining data and/or profiles characteristic for accumulators, in order to select suitable accumulators for large storage devices or battery power plants, the method according to the application also is usable for determining the state of degradation of battery or accumulator systems, wherein it is assumed that the degradation measurements of accumulator systems generally are based on the formation of an energy balance by taking account of models for the current cell behavior. All models assume that with increasing operating period the state-of-charge measurement is subject to a more or less pronounced drift, so that the capacitance measurement of an accumulator system involves an indefiniteness which greatly increases with time. Therefore, all accumulator systems regularly must approach defined states of charge, for example a full charge, in order to calibrate the determination of the state of charge, wherein for carrying out the calibration the accumulator system employs a fixed operating regime.

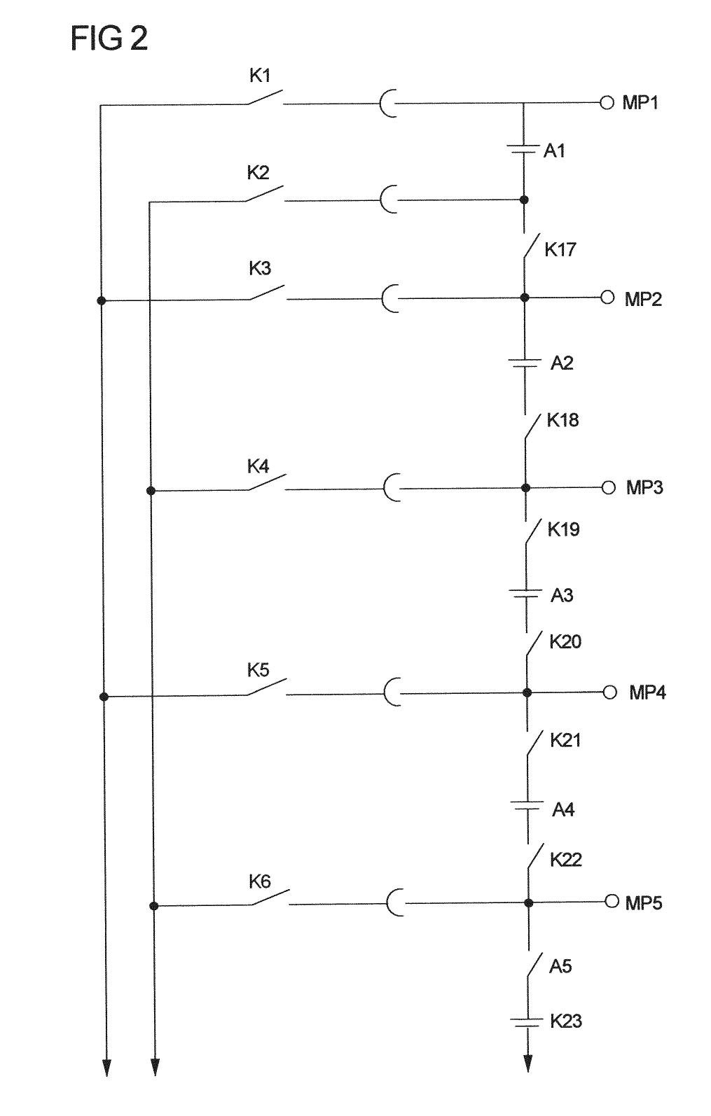

For applying the second measuring method, in which the remaining N−1 series-connected accumulators are recharged up to their respective capacitance limit and that accumulator which has reached its capacitance limit is separated from the series connection of the N−X accumulators, or in which the N−1 series-connected accumulators not yet discharged completely are connected to the load, discharged completely, and the accumulator discharged completely is separated from the series connection of the N−X accumulators, additional relay contacts are arranged in the connections of the series-connected accumulators A1 to A8, of which in the segment of the measuring device of FIG. 1 as shown in FIG. 2 the additional relay contacts k17 to k23 are shown in connection with the accumulators A1-A5.

When the accumulator A3 for example is the accumulator of the series-connected accumulators A1 to A8 which has the lowest capacitance, the relay contacts k19 and k20 closed previously for the series connection of the accumulators A1 to A8 are opened after fully charging the accumulator A3 and the relay contacts k4 and k5 are closed. When the accumulator with the lowest capacitance is the accumulator A1 in the measuring device according to FIG. 1, the relay contact k1 is opened, the relay contact k3 is closed and the relay contact k17 is opened after fully charging the accumulator A1.

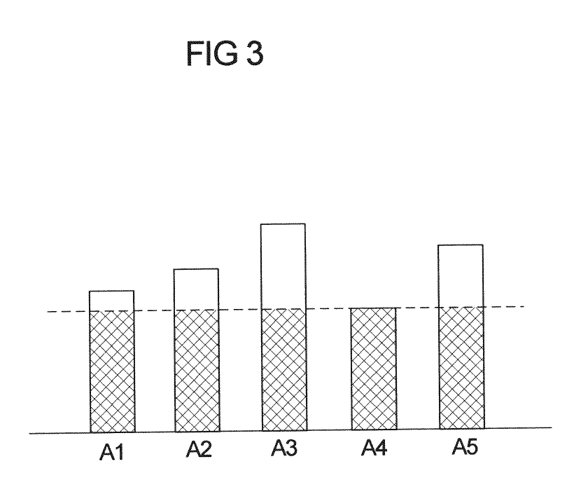

For a better understanding of the inventive method for determining the cycle stability of the accumulators A1-A8 the state of charge of five accumulators A1 to A5 is shown cross-hatched in FIG. 3, wherein it is assumed that the accumulator A4 has the lowest capacitance of the accumulators A1 to A5. With full charge of the accumulator A4, the accumulators A1, A2, A3 and A5 still have residual capacitances which in use of the first alternative of the method according to the application after separating the series connection in the second measurement phase are individually connected to the power supply unit 1 and recharged until reaching their capacitance limit. The measurement values at full charge, which correspond to the respective capacitance of the accumulators A1 to A5, usually the corresponding charging currents, charging voltage profiles and charging times, are stored and entered for example as measurement values into a representation of the capacitance of the respective accumulator over the number of charging and discharging operations.

In the third measurement phase the accumulator A4 as first one of the series-connected accumulators A1 to A5 likewise would be discharged completely, while the accumulators A1, A2, A3 and A5 still contain residual charges which in the fourth measurement phase would be discharged by individually discharging the accumulators A1, A2, A3 and A5 via the load until completely reaching the state of discharge.

In use of the second variant of the solution according to the application, after reaching the full charge of the accumulator A4 with the lowest capacitance and storage of the corresponding capacitance value, the accumulator A4 would be separated from the series connection of the accumulators A1 to A5, and in the second measurement phase the remaining accumulators A1, A2, A3 and A5 furthermore would be recharged connected in series, until according to the diagram of FIG. 3 the accumulator A1 has reached its capacitance limit, the corresponding measurement value is stored and the accumulator A1 is separated from the series connection of the remaining accumulators A1, A2, A3 and A5, so that the remaining series-connected accumulators A2, A3 and A5 are recharged further until reaching their respective capacitance limit.

When discharging the series-connected accumulators A1 to A5, the accumulator A4 likewise would be discharged first, while the accumulators A1, A2, A3 and A5 still have residual charges which in the fourth measurement phase are discharged further by successively separating the respective accumulator which is discharged completely.

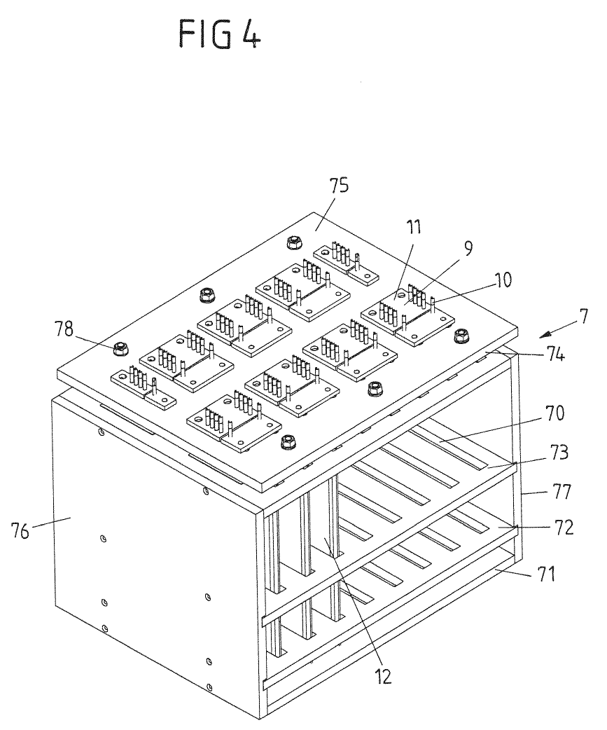

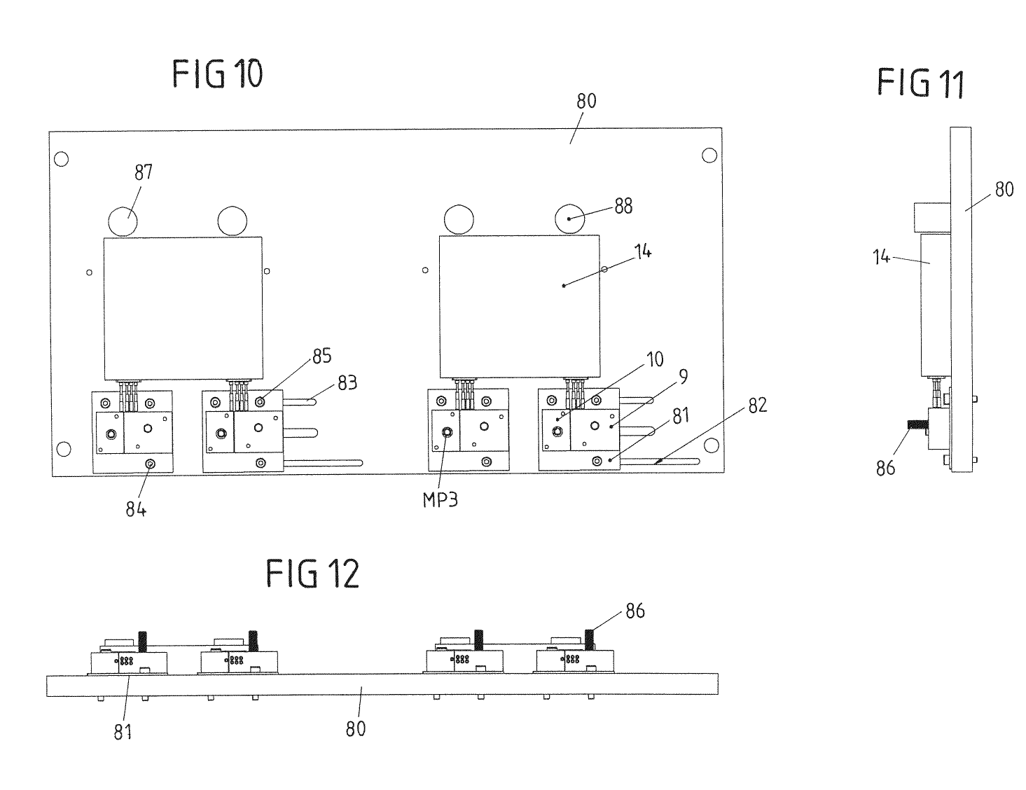

Apparatuses for carrying out the above-described method for measuring or testing accumulators will be explained in detail below with reference to FIGS. 4 to 16.

Due to the different geometrical structures of accumulators or accumulator cells, receptacles or holders adapted for different accumulator types are provided, which enable the measurement of several accumulators or accumulator cells at the same time. In the following Figures two different types of accumulator are referred to, without the application being limited to these receptacles or holders.

FIGS. 4 to 8 show a holder for accumulators of the pouch cell type, which consists of a holder 7 with a cuboid rack which includes a base plate 71, a cover plate 74 and side walls 76, 77 between which at least one, in this exemplary embodiment however two guide plates 72, 73 are arranged. The guide plates 72, 73 and the cover plate 74 include two parallel rows of guide slots 70 which are arranged at specified distances to each other to accommodate a specified number of pouch cells 12, 13 whose length corresponds to the maximum width of the pouch cells 12, 13.

Above the cover plate 74 a plate-shaped contact carrier 75 is arranged, which includes a number of contact plates 11 corresponding to the number of parallel guide slots 70, on which charging contacts 9 for charging and discharging the pouch cells 12, 13 and measurement contacts 10 for detecting the measurement signals are arranged separately from each other.

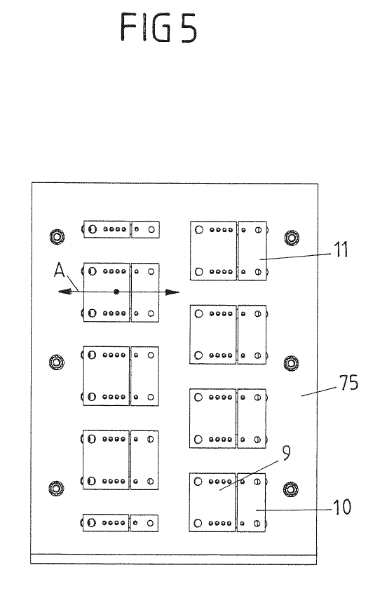

To adapt the charging and measurement contacts 9, 10 to pouch cells 12, 13 of different width, at least one of the two parallel rows of contact plates 11 is shiftably arranged in the guideways in direction of the double arrow A according to FIG. 5 in an alignment parallel to the guide slots 70.

Due to the different length of the pouch cells 12, 13, the holder 7 for accommodating the pouch cells 12, 13 is formed such that not only pouch cells 12, 13 of different width, but also of different length can be accommodated by the holder 7. For this purpose, at least one of the two guide plates 72, 73 is height-adjustable and both guide plates 72, 73 are insertable into the rack of the holder 7 so as to be rotatable in the plane by 180°, wherein as a result of a different distance of the guide slots 70 from the side walls 76, 77 in the one alignment of the guide plates 72, 73 the guide slots 70 of the cover plate 74 and of the guide plates 72, 73 are aligned with each other, while in the other position of the guide plates 72, 73 they are offset against each other. Depending on the length of the pouch cells 12, 13 either the upper guide plate 73 or the lower guide plate 72 or both guide plates is/are rotated by 180°.

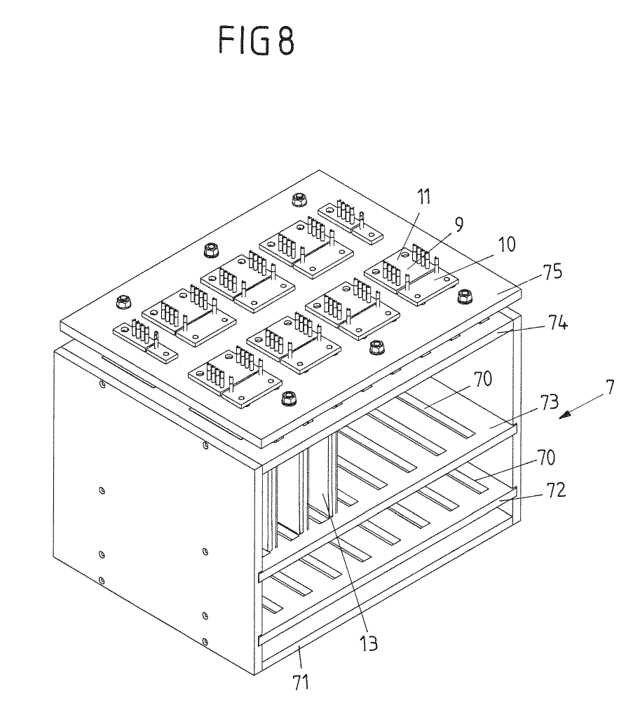

For short pouch cells 13—as shown in FIG. 8—the upper guide plate 73 is rotated by 180°, so that the same rest on the webs of the upper guide plate 73 formed between the guide slots 70. For pouch cells of medium length the lower guide plate 72 is rotated by 180°, so that these pouch cells rest on the webs of the lower guide plate 72 formed between the guide slots 70. For long pouch cells 12 the guide plates 72, 73—as shown in FIG. 4—are aligned such that their guide slots 70 are aligned with the cover plate 74, so that long pouch cells come to rest on the base plate 72.

The height adjustability of the guide plates 72, 73 provides for an adaptation of the holder 7 to different lengths of short and medium-length pouch cells 13.

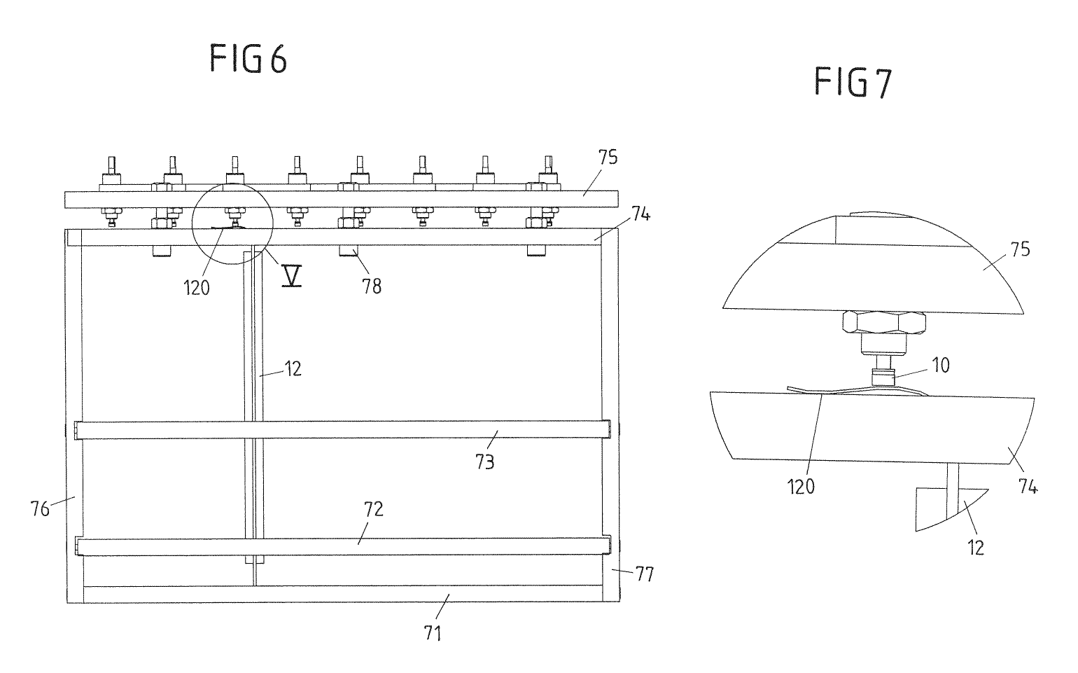

To connect the contact carrier 75 with the cover plate 74 and to firmly contact the charging and measurement contacts 9, 10 with the angled contact tabs 120 of the pouch cells 12, 13 according to FIGS. 6 and 7, screw connections 78 are provided, which are uniformly distributed over the surface of the contact carrier 75 to ensure uniform pressure.

In a top view FIG. 5 shows the contact plates 11 of at least one of the two parallel rows of contact plates with the charging and measurement contacts 9, 10 arranged thereon, which are adjustable in direction of the double arrow for adaptation to different contact distances. One contact row each is associated to a pouch cell 12, so that in this exemplary embodiment 8 pouch cells 12 can be inserted into the holder 7 for simultaneous and individual measurements and can be measured or tested via the charging and measurement contacts 9, 10.

FIG. 6 shows a side view of the holder 7 with a long pouch cell 12 inserted therein and its contact tabs 120 as well as the contact plates 11 arranged on the contact carrier 75 with the charging and measurement contacts 9, 10 arranged thereon. To connect the contact carrier 75 with the cover plate 74 of the rack of the holder 7 screw connections 78 are provided, which ensure a defined and firm connection with the contacts of the pouch cells 12.

FIG. 7 shows an enlarged representation of the detail V according to FIG. 6 with the bent contact tab 120 of the pouch cell 12, a measurement contact 10 non−positively connected with the contact tab 120, and the contact carrier 75 as well as the cover plate 74.

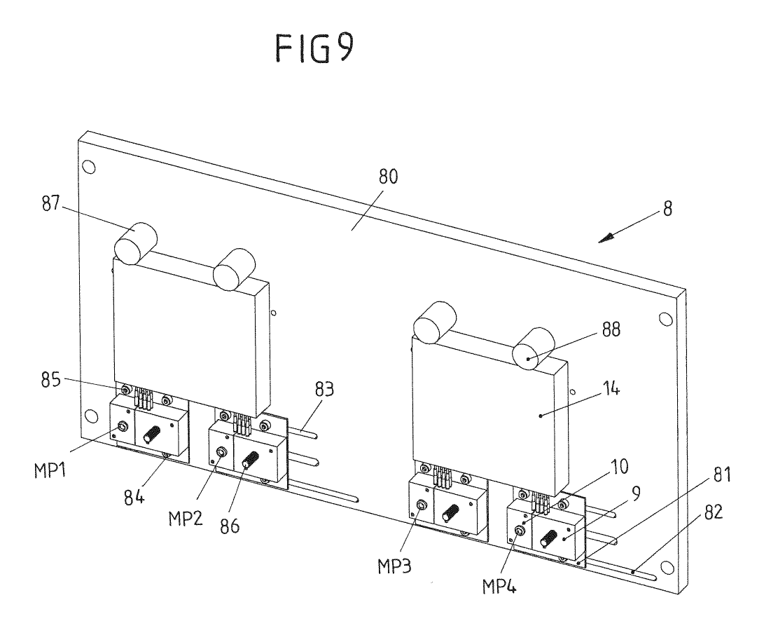

FIGS. 9 to 12 in a perspective view and in different views show a holder 8 for accommodating prismatic accumulators 14, which are arranged on a carrier plate 80 and are fixed in position by stops 87, 88. For measuring a plurality of prismatic accumulators 14, several carrier plates 80 are arranged one beside, above or behind the other in a holder corresponding to the holder 7 according to FIGS. 4 to 8. The charging and measurement contacts 9, 10 are arranged on circuit boards 81 which for adaptation to different contact distances of the prismatic accumulators 14 are adjustably mounted on guide rails 82, 83 in which bearing guides 84, 85 of the circuit boards 81 engage.

The charging contacts 9 are connected with the relay contacts k1 to k16 of the switching device 5 according to FIG. 1 via charging terminals 86, and the measurement contacts 10 are connected with measurement points MP1 to MP4 which are connected to the measuring device.

The holder 8 is steplessly variably adjustable for prismatic accumulators 14 with different outside dimensions by means of the stops 87, 88, wherein the circuit boards 81 shiftable along the guide rails 82, 83 provide for an adaptation of the charging and measurement contacts 9, 10 to different distances of the positive and negative poles of the prismatic accumulators 14. The electrical contact and the contact with measurement sensors is effected by means of shiftable copper blocks.

Both in the holder 7 for pouch cells 12, 13 corresponding to FIGS. 4 to 8 and in the holder 8 for prismatic accumulators 14 corresponding to FIGS. 9 to 12 the contacting of the pouch cells 12, 13 or prismatic accumulators 14 is effected by means of a screw-, clamp- and solder-free contacting and fixation of the pouch cells 12, 13 or prismatic accumulators 14 by means of spring contact pins whose contact surface is formed in the manner of a waffle iron, so that contacting also is ensured through oxide layers or dirt on the contact poles of the accumulators 12 to 14.

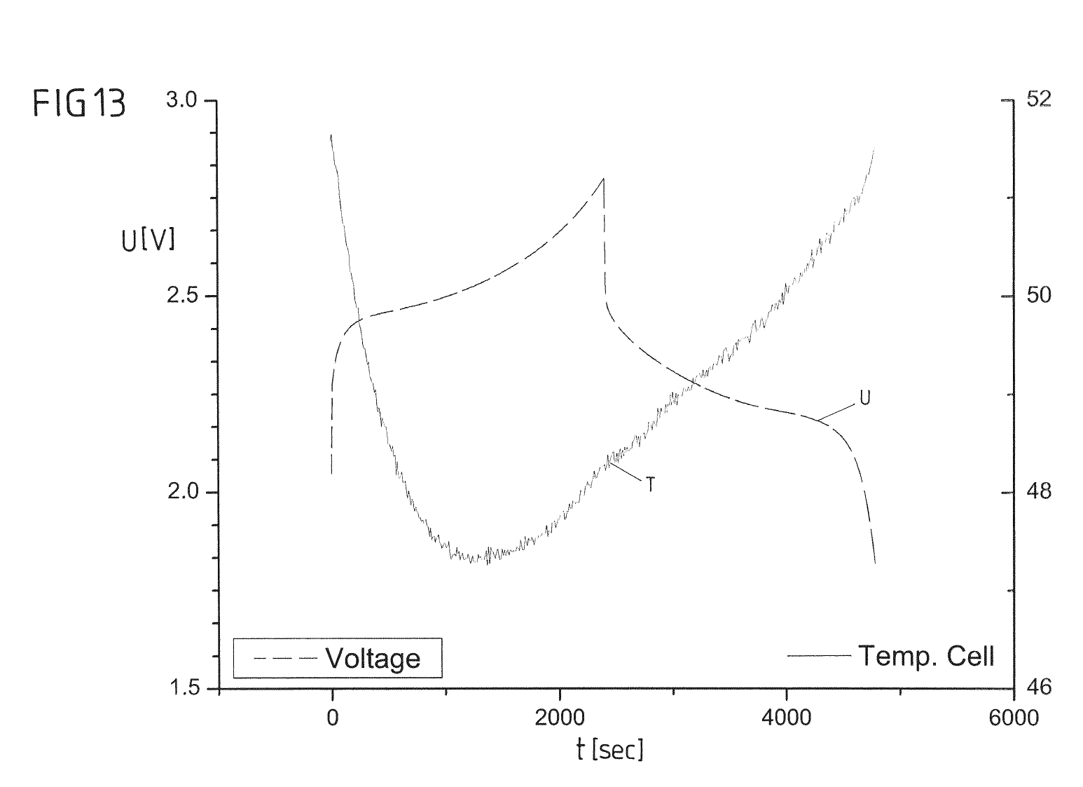

FIGS. 13 to 16 schematically show a selection of measurement curves which have been recorded by means of the measuring devices represented in FIGS. 1 and 4 to 12 and described above.

FIG. 13 shows the course of the cell voltage U [V] and the cell temperature T [° C.] of a measuring cell over the time t [sec] at an ambient temperature of 45° C. after 350 charging cycles. From 0 to about 2500 seconds, i.e. a time period of about 40 minutes, a charging operation is effected with 1C, i.e. with a charging current corresponding to the capacitance of the measurement cell, at which the cell voltage rises from 2.0 V to about 2.8 V and the cell temperature drops from about 52° C. to about 47° C. The charging operation is followed by a discharging operation likewise taking about 2500 seconds, in which the cell voltage drops to about 1.8 V, while the cell temperature rises to 51.5° C.

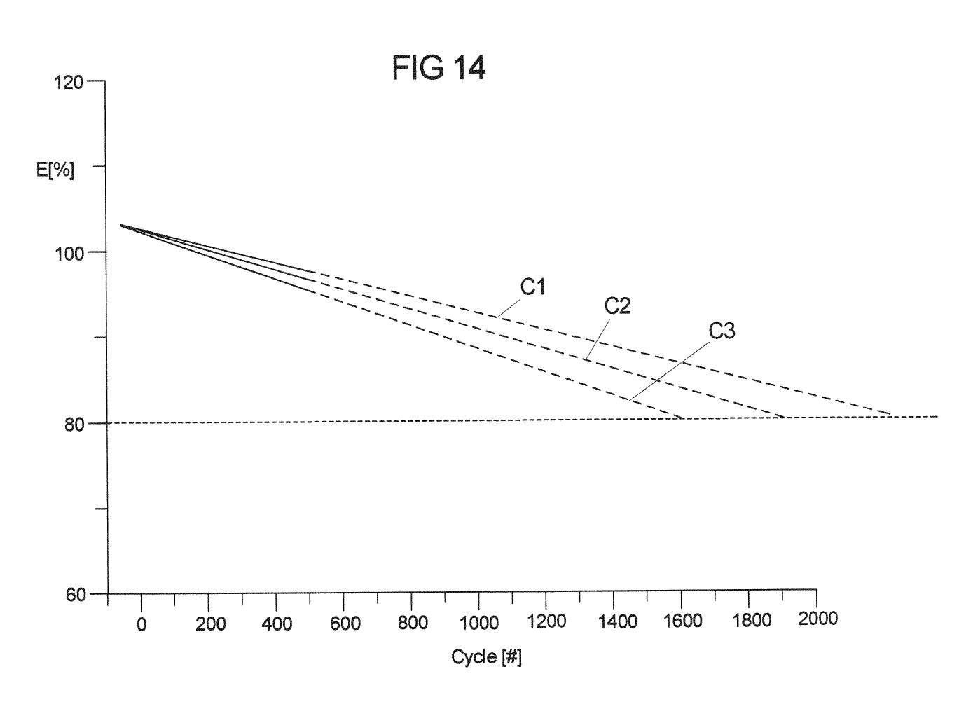

FIG. 14 shows the course of the energy of three measurement cells C1, C2 and C3 in percent E [%] over the number of charging and discharging cycles (Cycle [#]) in charging and discharging operations with 1C and an ambient temperature of 45° C. The actual measurements were recorded over about 550 cycles—shown in continuous lines—and extrapolated with broken lines. The measurement curves of all three measurement cells C1, C2 and C3 show an almost linear decrease of the energy E [%] with increasing charging and discharging cycles, wherein as service life end of a cell a decrease of the energy E [%] to 80% is assumed, which the measurement cell C3 reaches after about 1600 cycles and the measurement cell C2 after about 1900 cycles, while the measurement cell C1 stands up to more than 2000 cycles.

Since the measurements were made at an ambient temperature of T=45° C., a quadrupling of the service life end of the measurement cells can be assumed, as proceeding from an ambient temperature of 25° C. each temperature increase by 10° C. approximately corresponds to a doubling of the ageing of an accumulator cell. The curve of the measurements according to FIG. 14 thus shows a service life end of the measurement cell C3 at >7000 cycles, of the measurement cell C2 at >7600 cycles, and of the measurement cell C1 at >8000 cycles.

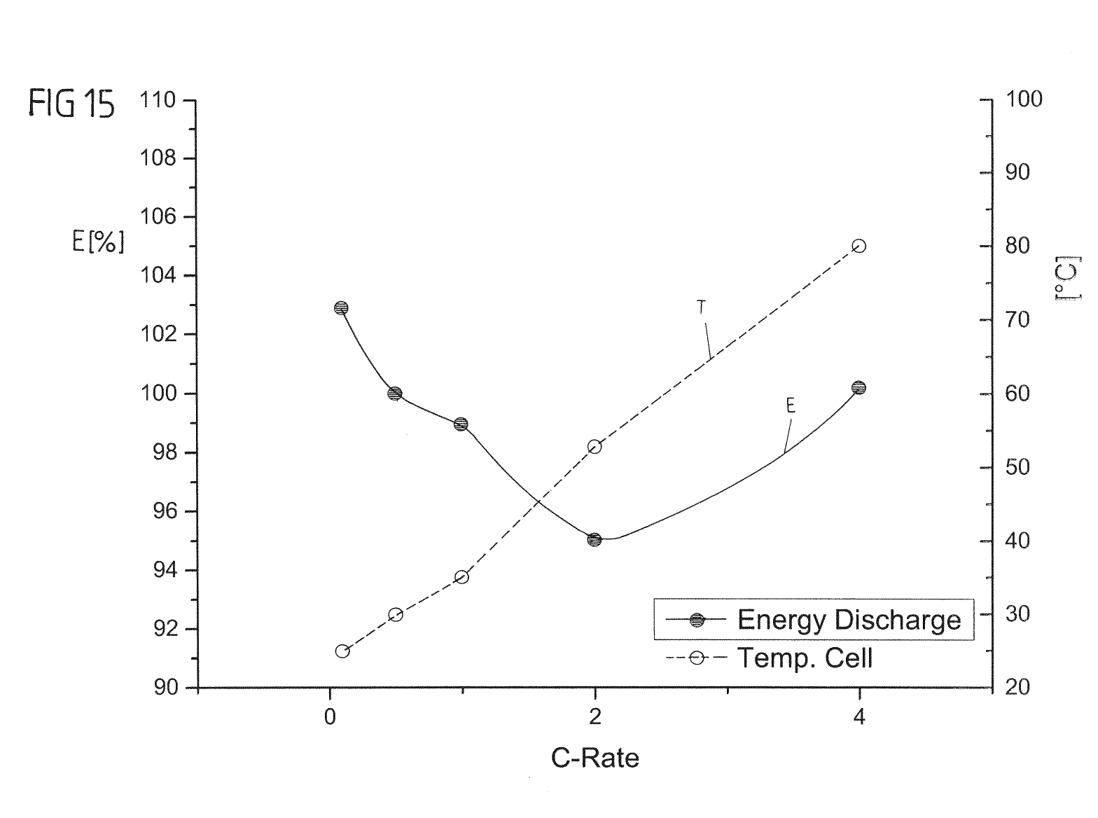

FIG. 15 shows the course of the discharge energy E [%] and the cell temperature T [° C.] of a measurement cell over the C-rate to assess the high-current capacity of the measurement cell and its temperature behavior without cooling or dissipation of the heat produced on charging of the measurement cell. While the energy or capacitance of the measurement cell initially drops with increasing C-rate, in order to rise again at C-rates above 2C, the cell temperature rises continuously with increasing C-rate from 25° C. to about 80° C.

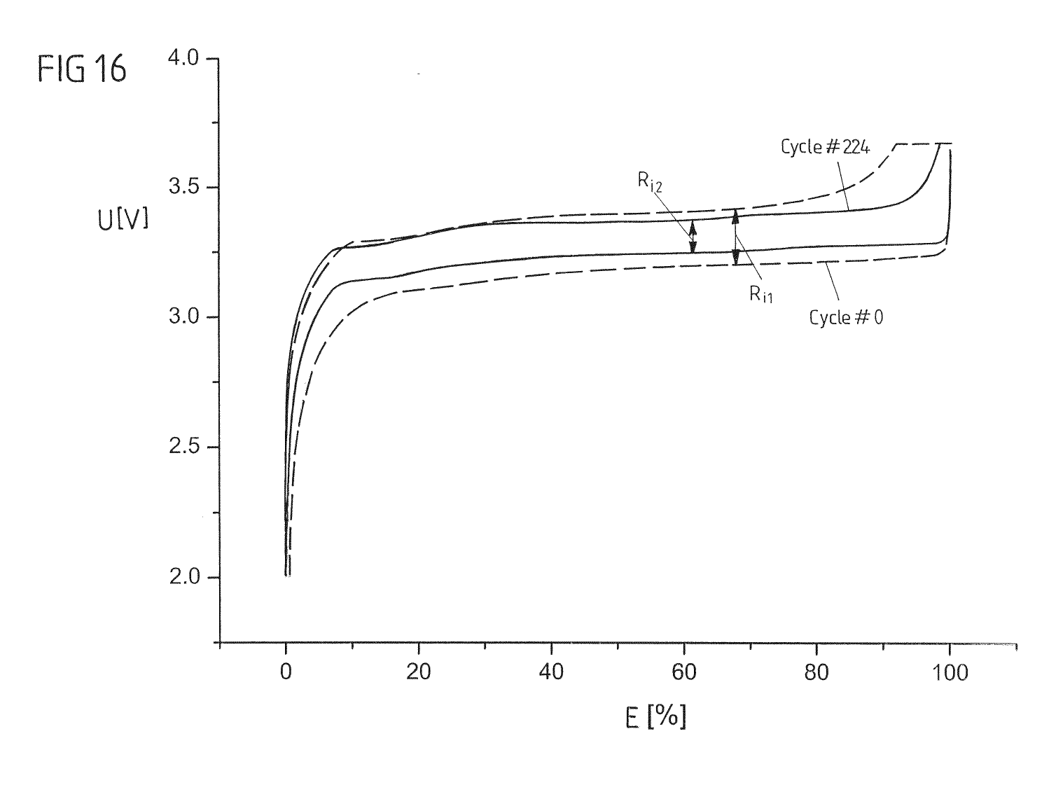

FIG. 16 shows the course of the cell voltage U [V] of a measurement cell over the energy E [%] of the measurement cell during charging and discharging without preceding charging and discharging cycle (Cycle #0) and after 224 cycles (Cycle #224). During artificial ageing the cell voltage changes significantly on charging and discharging and therefore can be used for a state-of-charge (SOC) definition. The internal resistance Rᵢ, of the measurement cell, which results from the difference of the curve on charging and discharging, also rises significantly with the number of cycles (Rᵢ₂>Rᵢ₁).

List of Reference Numerals

| | |
|---|---|
| 1 | power supply unit |
| 2 | electronic load |
| 3 | control device |
| 4 | interface |
| 5 | switching device |
| 6-8 | holder |
| 9 | charging contacts |
| 10 | measurement contacts |
| 11 | contact plates |
| 12 | long pouch cells |
| 13 | short pouch cells |
| 14 | prismatic accumulators |
| 70 | guide slots |
| 71 | base plate |
| 72, 73 | guide plates |
| 74 | cover plate |
| 75 | contact carrier |
| 76, 77 | side walls |
| 78 | screw connections |
| 80 | carrier plate |
| 81 | circuit board |
| 82, 83 | guide rails |
| 84, 85 | bearing guides |
| 86 | charging terminals |
| 87, 88 | stops |
| 120 | contact tabs |
| A1-A8 | accumulators |
| C1-C3 | measurement cells |
| k1-k23 | switching contacts (relay contacts) |
| MP1-MP8 | measurement points |

What is claimed is:

1. A method for measuring and testing the performance of a plurality of accumulators by determining at least one of data or profiles characteristic for the accumulators, the method comprising:
in a first measurement phase, N series-connected accumulators of the plurality of accumulators are connected to a power supply unit and by specifying predetermined first measurement parameters jointly are charged, until an accumulator having the lowest capacitance of the N-series connected accumulators is charged completely and a plurality of measurement values corresponding to the energy of the accumulator having the lowest capacitance are stored, and the accumulator having the lowest capacitance is separated from the series connection of the N series-connected accumulators;
in a second measurement phase, the remaining N−1 accumulators are recharged to a full charge and a plurality of measurement values corresponding to energy of each of the N−1 accumulators are stored;
in a third measurement phase, the N series-connected accumulators are connected to a load and are discharged by specifying predetermined second measurement parameters, wherein measurement values are recorded until an accumulator having the lowest capacitance of the N series-connected accumulators is discharged completely and is separated from the series connection; and
in a fourth measurement phase, the N−1 accumulators of the N series-connected accumulators not yet discharged completely are connected to the load and discharged completely, wherein N is an integer>1.

2. The method according to claim 1, wherein in the second measurement phase, the series connection of the N−1 accumulators is separated and the accumulators not yet charged completely are individually connected to the power supply unit and recharged up to their respective full charge, and a measurement value corresponding to the capacitance of each of the N−1 accumulators is stored, and wherein in the fourth measurement phase, the series connection of the N series-connected accumulators is separated and the N−1 accumulators not yet discharged completely are individually connected to the load and discharged completely, wherein N is an integer>1.

3. The method according to claim 1, wherein in the second measurement phase the remaining N−1 series-connected accumulators are recharged up to their respective capacitance limit and a plurality of measurement values corresponding to the energy of that accumulator are stored and the accumulator which has reached its capacitance limit is separated from the series connection of the N−X accumulators, wherein in the fourth measurement phase, the N−1 series-connected accumulators not yet discharged completely are connected to the load, discharged completely and the respective completely discharged accumulator is separated from the series connection of the N−X accumulators, and wherein N and X are integers with N>1 and 2<X<N.

4. The method according to claim 1, wherein each of the measurement phases is repeated at least once.

5. The method according to claim 1, wherein in the first and second measurement phases, the N series-connected accumulators are charged until reaching an end-of-charge voltage by specifying the predetermined first measurement parameters, and wherein in the third and fourth measurement phases are discharged until reaching the end-of-discharge voltage.

6. The method according to claim 1, wherein at least one of the first or second measurement parameters includes charging current, charging voltage, charging time, or temperature of at least one of the series-connected accumulators.

7. The method according to claim 1, wherein in a fifth measurement phase, each of the N series-connected accumulators is individually connected to the power supply unit and the load and is charged and discharged at least once to determine specific properties of the N series-connected accumulators, wherein the specific properties include at least one of capacitance, impedance, internal resistance, record measurement, load, temperature, ageing, or degradation curves.

8. The method according to claim 1, wherein in each of the measurement phases, a preferably programmed, predetermined cyclization or load profile is carried out for the accelerated ageing, capacitance degradation, increase in impedance, or increase in internal resistance of at least one of the N series-connected accumulators.

9. An apparatus for carrying out a method for measuring and testing the performance of a plurality of accumulators by determining at least one of data and profile characteristics for the accumulators, wherein in a first measurement phase, N series-connected accumulators of the plurality of accumulators are connected to a power supply unit and by specifying predetermined first measurement parameters jointly are charged, until an accumulator having the lowest capacitance of the N-series connected accumulators is charged completely and a plurality of measurement values corresponding to the energy of the accumulator having the lowest capacitance are stored, and the accumulator having the lowest capacitance is separated from the series connection, wherein in a second measurement phase, the remaining N−1 accumulators are recharged up to their full charge and a plurality of measurement values corresponding to the energy of each of the N−1 accumulators are stored, wherein in a third measurement phase, the N series-connected accumulators are connected to a load and are discharged by specifying predetermined second measurement parameters, wherein measurement values are recorded until an accumulator having the lowest capacitance of the N series-connected accumulators is discharged completely and is separated from the series connection, and wherein in a fourth measurement phase, the N−1 accumulators of the N series-connected accumulators not yet discharged completely are connected to the load and discharged completely, wherein N is an integer >1, the apparatus comprising:
a holder for accommodating the N series-connected accumulators with different dimensions;
a switching device with controllable switching contacts for the series connection of the N series-connected accumulators and connection of the N series-connected accumulators to a power supply unit;
a load; and
a measuring device for separating the series connection, and for individually connecting each individual accumulator of the N series-connected accumulators to the power supply unit, the load, and the measuring device.

10. The apparatus according to claim 9, wherein the switching device contains a plurality of controllable switching contacts corresponding to the number of N series-connected accumulators to be measured, wherein in the first measurement phase, the accumulators are connectable in series to the power supply unit, to the load, and to the measuring device, and wherein after the first measurement phase, the series connection can be separated and in the second measurement phase, each individual accumulator can be connected to the power supply unit, to the load, and to the measuring device.

11. The apparatus according to claim 9, wherein the load includes an electronic load, wherein for zero-point lowering on charging and discharging of the accumulators, a negative pole of the electronic load is connected with a negative pole of a voltage source, and wherein a positive pole of the voltage source is connected to a negative pole of the power supply unit via a Z-diode.

12. The apparatus according to claim 9, wherein the switching contacts of the switching device include a relay circuit with a plurality of relay contacts corresponding to twice the number of N series-connected accumulators to be connected in series.

13. The apparatus according to claim 9, wherein the charging contacts and the measurement contacts of the measurement sensors include pressure pin contacts.

14. The apparatus according to claim 9, wherein the holder includes steplessly adjustable receptacles for one or more accumulators of the N series-connected accumulators with different outside dimensions or distances between electrical contacts of the one or more accumulators.

15. The apparatus according to claim 9, wherein a first holder is provided for one or more accumulators of the N series-connected accumulators formed as pouch cells, wherein the pouch cells include a box-shaped rack with a base plate, a cover plate, and at least one guide plate between the cover plate and the base plate, wherein the cover plate and the at least one guide plate include guide slots for accommodating the pouch cells.

16. The apparatus according to claim 15, wherein a length of the guide slots corresponds to a maximum width of the pouch cells.

17. The apparatus according to claim 16, wherein the at least one guide plate is insertable into a space formed between the cover plate and the base plate so as to be rotatable in a plane by 180° such that in a first alignment of the guide plate for accommodating long pouch cells the guide slots arranged in the guide plate are aligned with the guide slots arranged in the cover plate and in a second alignment of the guide plate for accommodating short pouch cells the guide slots arranged in the guide plate are arranged offset to the guide slots arranged in the cover plate.

18. The apparatus according to claim 15, wherein a contact carrier with charging and measurement contacts is laterally movable in the plane of the contact carrier and is mountable on the cover plate.

19. The apparatus according to claim 18, wherein a second holder includes at least one carrier plate with receptacles for prismatic accumulators and guide rails for guiding circuit boards, wherein the guide rails are adjustable parallel to the plane of the electrical contacts of the accumulators.

20. The apparatus according to claim 19, wherein the guide rails are steplessly adjustable and the receptacles for prismatic accumulators include stops that are adjustably arranged on the carrier plate.
